(19) United States
(12) Patent Application Publication
(10) Pub. No.: US 2010/0093114 A1
(43) Pub. Date: Apr. 15, 2010

(54) METHOD OF SEARCHING FOR KEY SEMICONDUCTOR OPERATION WITH RANDOMIZATION FOR WAFER POSITION

(75) Inventors: YIJ CHIEH CHU, TAIPEI COUNTY 241 (TW); CHUN CHI CHEN, TAIPEI CITY 115 (TW); YUN-ZONG TIAN, TAICHUNG COUNTY 422 (TW); CHENG-HAO CHEN, TAIPEI CITY 105 (TW)

Correspondence Address: ROSENBERG, KLEIN & LEE, 3458 ELLICOTT CENTER DRIVE-SUITE 101, ELLICOTT CITY, MD, 21043, US

(73) Assignee: INOTERA MEMORIES, INC., TAOYUAN COUNTY 333 (TW)

(21) Appl. No.: 12/330,846

(22) Filed: Dec. 9, 2008

(30) Foreign Application Priority Data
Oct. 15, 2008 (TW) 97139536

(51) Int. Cl. H01L 21/02

(52) U.S. Cl. 438/14; 438/5; 257/E21.002

(57) ABSTRACT

A method of searching for the key semiconductor operation with randomization for wafer position, comprising: recording the wafer position and the wafer yields of a plurality of wafer ID respectively corresponding to a plurality of semiconductor operations; establishing a matrix model which describes the matrix set for wafer yields of the plurality of wafer ID; analyzing the matrix model, further computing the matrix set for wafer yields of the wafer ID, thereby acquiring the weightings of the randomized wafer positions in such semiconductor operations; and searching for a key semiconductor operation among the plurality of semiconductor operations; herein, by using a local regression model to estimate the wafer position effect, computing the weighting of the position effect in each semiconductor operation based on the estimated position effect and the randomized wafer yield, higher weighting thereof indicates the key semiconductor operation having greater position effect in the aforementioned semiconductor process.

### BACKGROUND OF THE INVENTION

1. Field of the Invention

The present invention relates to a method of searching for key semiconductor operation; especially, to a method of searching for key semiconductor operation with randomization for wafer position.

2. Description of Related Art

Conventional semiconductor fabs are generally equipped with various semiconductor machines for the necessary semiconductor process in order to deal with wafers in a wafer lot to pass through many semiconductor operations, e.g. operations like chemical mechanical polishing (CMP), cleaning, etching, lithography, coating, and so on. The fabrication of an integrated circuit (IC) device generally requires nearly up to 600 semiconductor operations.

As shown in FIG. 1, most wafers are stored in a container, e.g. a cassette, and each container may hold at most 25 pieces of wafers; afterward, the cassette is loaded into a carrier (also referred as a cassette transporter), such as the Standard Mechanical Interfaces (SMIFs) or 12-inch Front Opening Unified Pods (FOUPs), thereby allowing transportation in a semiconductor fab. The cassette may consists of a plurality of wafer positions to hold the wafer itself, sequentially passing through the semiconductor operation 1, semiconductor operation 2, . . . , semiconductor operation n, so as to complete the entire semiconductor fabrication process.

However, after completion of the entire semiconductor fabrication process, the wafer yield 12 respectively corresponding to the wafer position 104 of such wafer grooves may tend to demonstrate a non-uniform bell curve 106 (also referred as Gaussian Distribution), which is the so-called spatial effect of the wafer position 104, causing certain products in each wafer lot unable to conform to the required industrial standards, thus leading to undesirable increase in production cost.

Accordingly, the inventors of the present invention have considered the aforementioned improvable defects, and, based on long-term field experiences in relevant fields as well as profound observations and studies, in conjunction with practical applications of theories, hereby proposed the present invention of reasonable design and effectiveness in resolution of the above-said drawbacks.

### SUMMARY OF THE INVENTION

Therefore, the objective of the present invention is to provide a method of searching for key semiconductor operation with randomized wafer position, so as to maintain uniformity of wafer yield in the semiconductor process.

In accordance with the objective set forth hereinbefore, the present invention provides a method of searching for key semiconductor operation with randomized wafer position, comprising the following steps: recording the wafer position of a plurality of wafer ID respectively corresponding to a plurality of semiconductor operations, as well as the wafer yields of the plurality of wafer ID; establishing a matrix model which describes the matrix set for wafer yields of the plurality of wafer ID; analyzing the matrix model, further computing the matrix set for wafer yield of the wafer ID, thereby acquiring the weighting of the randomized wafer position in such semiconductor operations; and searching for the key semiconductor operation among the plurality of semiconductor operations.

The present invention provides the following advantageous effects:

(1) by using a local regression model, it is possible to estimate the non-linear effect of wafer position randomization in the semiconductor operations;

(2) field engineers may use the randomization of wafer position in the semiconductor operations to define the key semiconductor operation having higher position effect in the semiconductor process;

(3) by defining the key semiconductor operation in the semiconductor process, it is allowed to significantly increase the efficiency of wafer position randomization.

To further facilitate better understanding of the characteristics and technical contents of the present invention, references are made to the following detailed descriptions and appended drawings; whereas the appended drawings are simply referential and illustrative, rather than being employed to restrict the scope of the present invention thereto.

### BRIEF DESCRIPTION OF THE DRAWINGS

FIG. 1 shows a wafer yield diagram of a conventional semiconductor process.

FIG. 2 shows a flowchart of the method of searching for key semiconductor operation with randomization for wafer position according to a first embodiment of the present invention.

FIG. 3 shows a table (1) of the method of searching for key semiconductor operation with randomization for wafer position according to the first embodiment of the present invention.

FIG. 4 shows a curve diagram of the method of searching for key semiconductor operation with randomization for wafer position according to the first embodiment of the present invention.

FIG. 5A shows a table (2) of the method of searching for key semiconductor operation with randomization for wafer position according to the first embodiment of the present invention.

FIG. 5B shows a table (3) of the method of searching for key semiconductor operation with randomization for wafer position according to the first embodiment of the present invention.

FIG. 5C shows a table (4) of the method of searching for key semiconductor operation with randomization for wafer position according to the first embodiment of the present invention.

FIG. 6 shows a flowchart of the method of searching for key semiconductor operation with randomization for wafer position according to a second embodiment of the present invention.

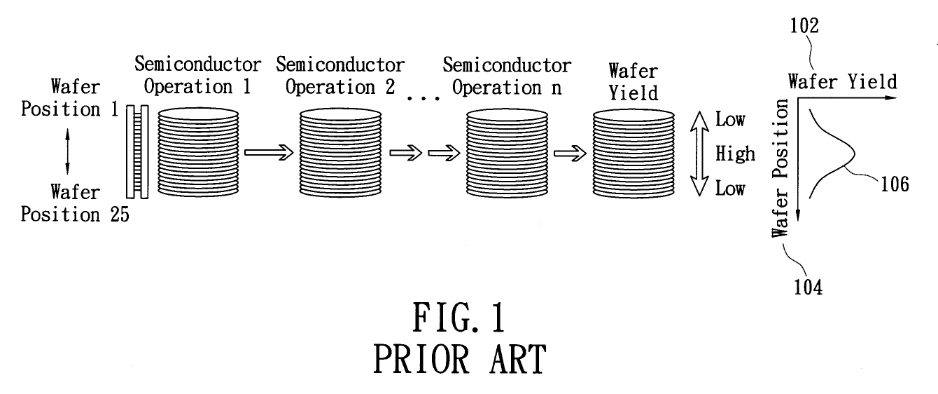

### DETAILED DESCRIPTION OF PREFERRED EMBODIMENTS

### Embodiment 1

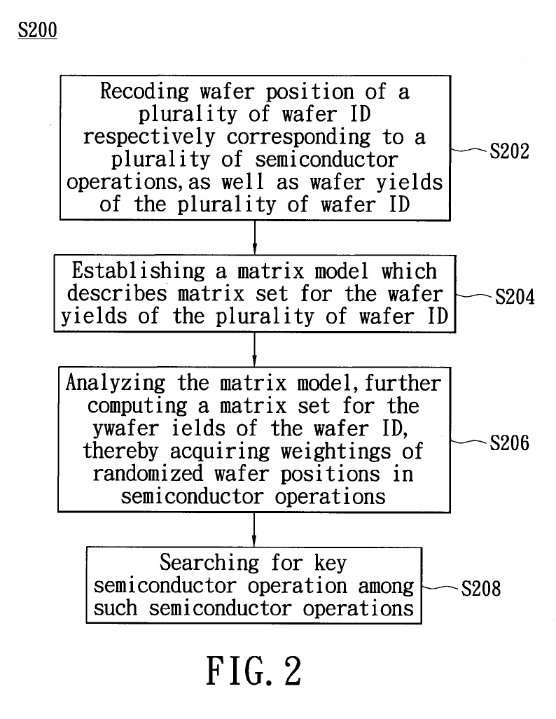

Refer now to FIG. 2, in which a method S200 of searching for key semiconductor operation with randomization for wafer position according to the present invention is shown, comprising the following steps:

Executing STEP S202, which records the wafer position of a plurality of wafer ID respectively corresponding to a plurality of semiconductor operations, as well as the wafer yields of the plurality of wafer ID. Such semiconductor operations may include wafer cleaning operation, ion implantation operation, thin-film operation, lithography operation, and etching operation.

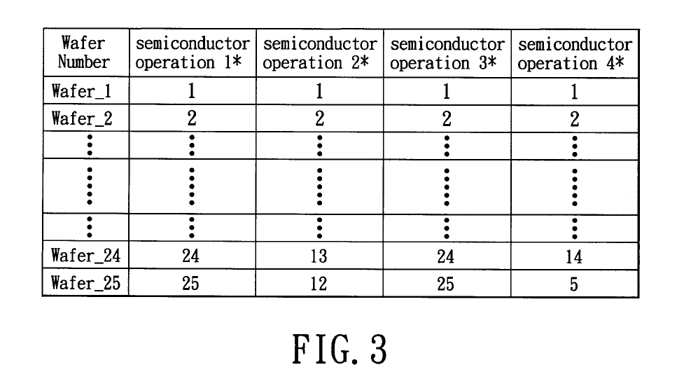

In the present embodiment, referring to FIG. 3, it initially divides the wafer positions in such semiconductor operations into the fixed wafer position and the randomized wafer position, then classifying the semiconductor operations having the same fixed wafer position into a group.

Executing STEP S204, which establishes a matrix model describing the matrix set for wafer yields of the plurality of wafer ID, as formulated hereunder:

$$Y = [ \begin{matrix}{Y}_{1} \\ {Y}_{2}\end{matrix} ] = [ \begin{matrix}{\hat{S}}_{1} \\ {\hat{S}}_{2}\end{matrix} ] \cdot W + E ,$$

wherein Y indicates the matrix set for wafer yields of the wafer ID, Y₁ is the wafer yields of the fixed wafer position in the semiconductor operations, Y₂ is the wafer yields of the randomized wafer position in the semiconductor operations, Ŝ₁ is the estimation of the wafer yields of the fixed wafer position in the semiconductor operations (in other words, Ŝ₁ is the estimation value of Y₁), Ŝ₂ the result value of the wafer yields of the randomized wafer position in the semiconductor operations, W is the position effect weighting of the semiconductor operations, and E is the residue of the local regression model. Therein, the estimation of wafer yield of the fixed wafer position in the semiconductor operations (i.e. Ŝ₁) is acquired by a locally weighted scatterplot smoothing (Lowess), then used to predict the result value of the wafer yield of the randomized wafer position in the semiconductor operations. That is, in the present embodiment, by using the local regression model to estimate the wafer position effect, it divides the wafer yields into the position effect and unexplained residue in each semiconductor operation with different weighting.

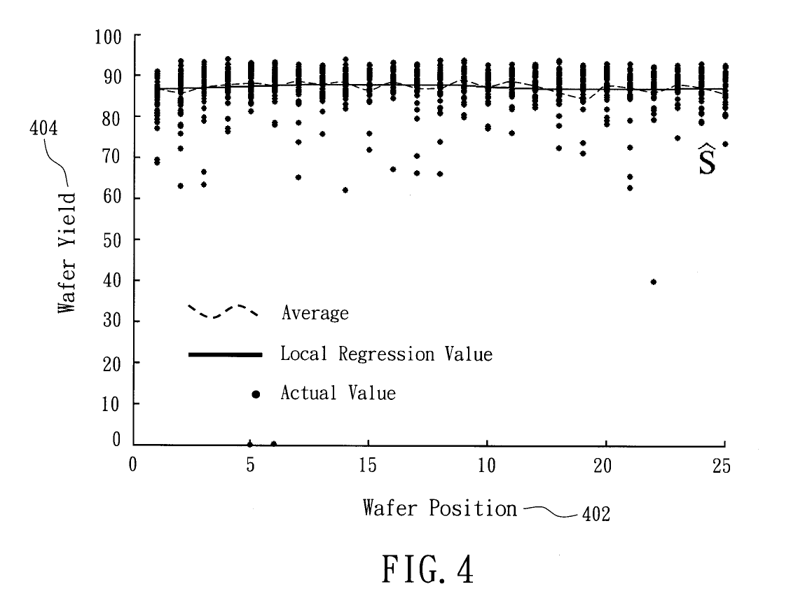

Executing STEP S206 which, by referring to FIG. 4 depicting the relationship between the wafer position 402 and the wafer yield 404, herein · is an actual value of the wafer yield, - - - - is an average value of the wafer yield, and — is a local regression value of the wafer yield which indicates the estimation of wafer yield of the fixed wafer position in the semiconductor operations (i.e. Ŝ). To analyze the matrix model, further computing the matrix set for wafer yields of the wafer ID, thereby acquiring the weightings of the randomized wafer positions in the semiconductor operations; herein higher weighting of the randomized wafer positions in such semiconductor operations indicates greater extent of influence on the wafer yield corresponding to the ID in the semiconductor operations.

To further illustrate, during analysis of the matrix model, after normalization of the relationship between the wafer position and the wafer yield, the weighting of the randomized wafer position in the semiconductor operations can be derived through matrix statistic calculations; however, the above-said matrix statistic calculations are not crucial, hereby thus omitted for brevity.

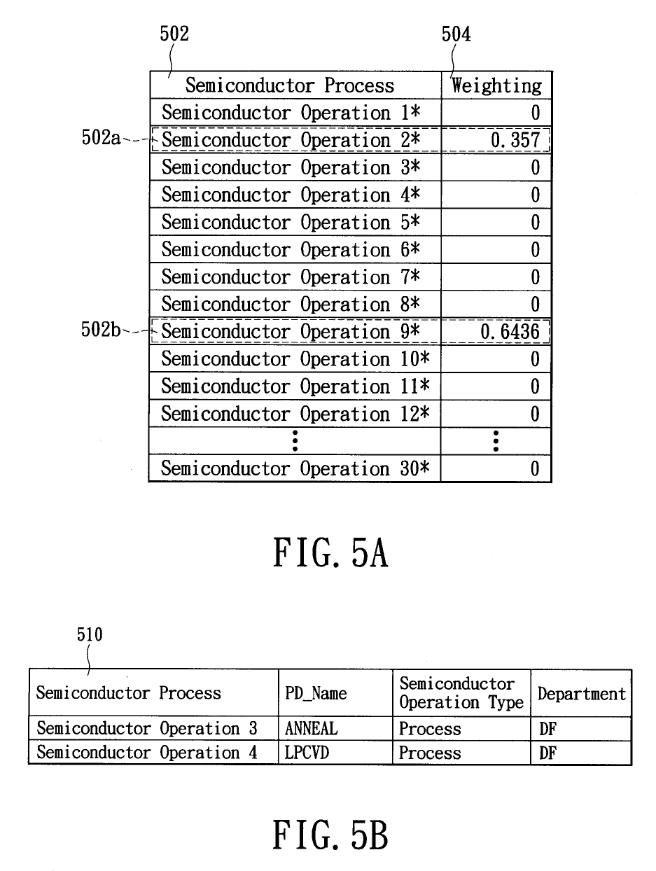

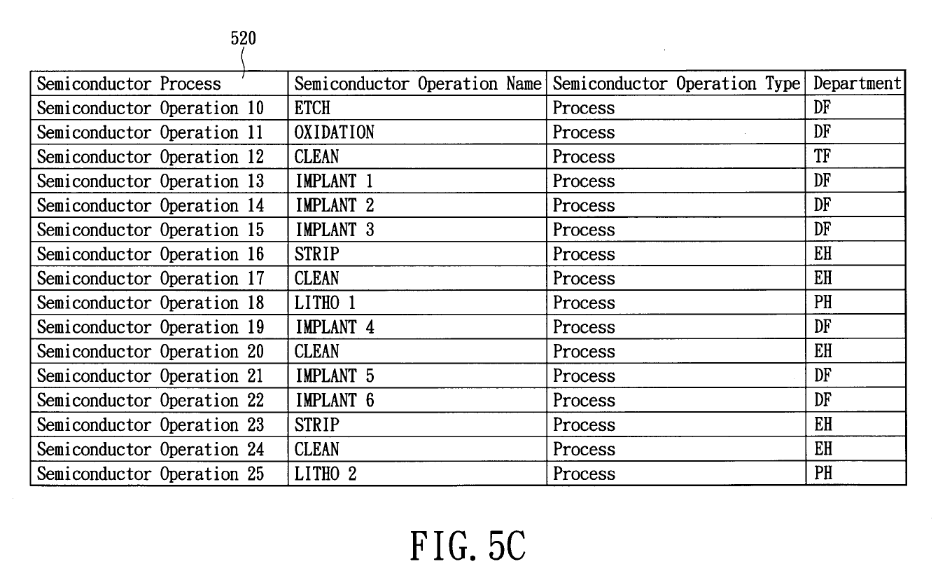

Executing STEP S208, which searches for the key semiconductor operation among the semiconductor operations. In the present embodiment, referring to FIGS. 5A to 5C, based on the weighting 504 corresponding to the semiconductor process 502, the semiconductor operation 2* (502a, 510) and the semiconductor operation 9* (502b, 520) are the key semiconductor operations among those semiconductor operations.

For example, a field engineer may use such key semiconductor operations 2* and 9* (502a, 510; 502b, 520) to perform randomization of wafer position, so as to reduce the spatial effect of wafer position, thereby obtaining uniform wafer yield on those wafer ID.

### Second Embodiment

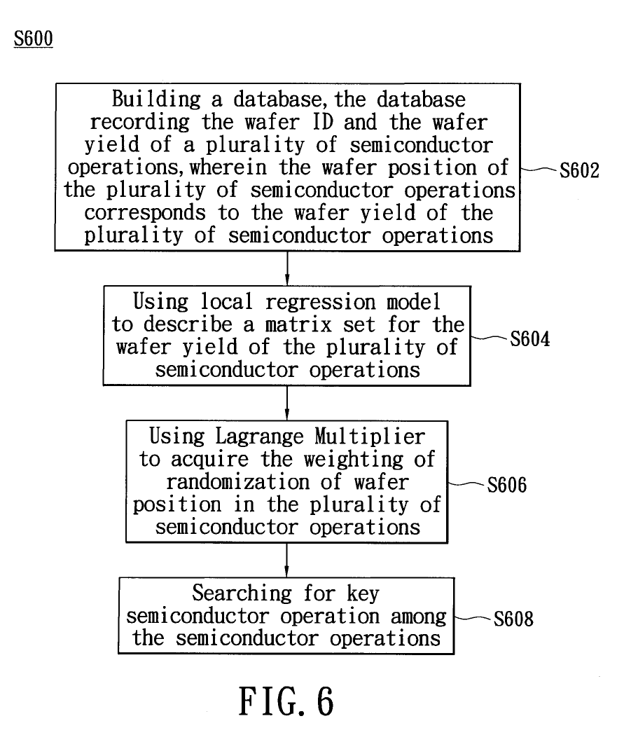

Refer now to FIG. 6, in which another method S600 of searching for key semiconductor operation with randomization for wafer position according to the present invention is shown, comprising the following steps:

executing STEP S602, which builds a database recording the wafer ID of a plurality of semiconductor operations and the wafer yield of the plurality of semiconductor operations, wherein the wafer position of the plurality of semiconductor operations corresponds to the wafer yield of the plurality of semiconductor operations; executing STEP S604, which uses a local regression model to describe a matrix set for the wafer yield of the semiconductor operations; executing STEP S606, which uses the Lagrange Multiplier to acquire the weighting of randomization of wafer position in the semiconductor operations; executing STEP S608, which searches for the key semiconductor operation among the semiconductor operations.

Therein the Lagrange Multiplier is a method for limit evaluation. For example, there exist two variables and it is to find the limit for a function of such two variables; however, suppose the range of the two variables are bounded by another function of these two variables, it may generate a multiplier of the linear relationship between the function of the two variables and the said another function, which the multiplier being referred as a Lagrange Multiplier.

Comparing the present invention with prior art, the following advantageous effects can be obtained:

(1) by using the local regression model, it is possible to estimate the non-linear effect of the randomized wafer position;

(2) field engineers may use the randomization of wafer position in the semiconductor operations to define the key semiconductor operation having higher position effect in the semiconductor process;

(3) by defining the key semiconductor operation in the semiconductor process, it is allowed to locate the key semiconductor operation, thereby achieving the objective of process performance enhancement.

The disclosure illustrated above simply sets forth the preferred embodiments of the present invention, rather than intending to limit the scope of the present invention thereto; it is noted that all effectively equivalent changes, modifications and substitutions made in accordance with the disclosure of the present invention and appended drawings are reasonably deemed as being encompassed within the legally protected range of the present invention defined by the following claims.

What is claimed is:

1. A method of searching for key semiconductor operation with randomization for wafer position, comprising the following steps:
recording the wafer position of a plurality of wafer ID respectively corresponding to a plurality of semiconductor operations, as well as the wafer yields of the plurality of wafer ID;
establishing a matrix model which describes the matrix set for wafer yields of the plurality of wafer ID;
analyzing the matrix model, further computing the matrix set for wafer yield of the wafer ID, thereby acquiring the weighting of the randomized wafer position in such semiconductor operations; and
searching for the key semiconductor operation among the plurality of semiconductor operations.

2. The method of searching for key semiconductor operation with randomization for wafer position according to claim 1, wherein said semiconductor operations include wafer cleaning operation, ion implantation operation, thin-film operation, lithography operation, and etching operation.

3. The method of searching for key semiconductor operation with randomization for wafer position according to claim 1, wherein the said matrix models can be formulated as:
$$Y = [ \begin{matrix}{Y}_{1} \\ {Y}_{2}\end{matrix} ] = [ \begin{matrix}{\hat{S}}_{1} \\ {\hat{S}}_{2}\end{matrix} ] \cdot W + E$$
wherein Y indicates the matrix set for wafer yields of the wafer ID, Y₁ is the wafer yields of the fixed wafer position in the semiconductor operations, Y₂ is the wafer yields of the randomized wafer position in the semiconductor operations, Ŝ₁ is the estimation of the wafer yields of the fixed wafer position in the semiconductor operations, Ŝ₂ is the result value of the wafer yields of the randomized wafer position in the semiconductor operations, W is the position effect weighting of the randomized wafer position in the semiconductor operations, and E is the residue of the local regression model.

4. The method of searching for key semiconductor operation with randomization for wafer position according to claim 3, wherein the estimation of wafer yield of the fixed wafer position in the semiconductor operations is acquired by a locally weighted scatterplot smoothing (Lowess), then used to predict the result value of the wafer yield of the randomized wafer position in the semiconductor operations.

5. The method of searching for key semiconductor operation with randomization for wafer position according to claim 3, wherein higher weighting of the randomized wafer positions in the semiconductor operations indicates greater extent of influence on the wafer yield corresponding to the ID in the semiconductor operations.

6. The method of searching for key semiconductor operation with randomization for wafer position according to claim 3, wherein lower weighting of the randomized wafer positions in the semiconductor operations indicates smaller extent of influence on the wafer yield corresponding to the ID in the semiconductor operations.

7. A method of searching for key semiconductor operation with randomization for wafer position, comprising the following steps:
building a database, the database recording the wafer ID of a plurality of semiconductor operations and wafer yield of the plurality of semiconductor operations, wherein the wafer position of the plurality of semiconductor operations corresponds to the wafer yield of the plurality of semiconductor operations;
using a local regression model to describe a matrix set for the wafer yield of the semiconductor operations;
using the Lagrange Multiplier to acquire the weighting of randomization of wafer position in the semiconductor operations; and
searching for the key semiconductor operation among the semiconductor operations.

8. The method of searching for key semiconductor operation with randomization for wafer position according to claim 7, wherein said semiconductor operations include wafer cleaning operation, ion implantation operation, thin-film operation, lithography operation, and etching operation.

9. The method of searching for key semiconductor operation with randomization for wafer position according to claim 7, wherein the said matrix models can be formulated as:
$$Y = [ \begin{matrix}{Y}_{1} \\ {Y}_{2}\end{matrix} ] = [ \begin{matrix}{\hat{S}}_{1} \\ {\hat{S}}_{2}\end{matrix} ] \cdot W + E$$
wherein Y indicates the matrix set for wafer yields of the wafer ID, Y₁ is the wafer yields of the fixed wafer position in the semiconductor operations, Y₂ is the wafer yields of the randomized wafer position in the semiconductor operations, Ŝ₁ is the estimation of the wafer yields of the fixed wafer position in the semiconductor operations, Ŝ₂ is the result value of the wafer yields of the randomized wafer position in the semiconductor operations, W is the position effect weighting of the randomized wafer position in the semiconductor operations and, E is the residue of the local regression model.

10. The method of searching for key semiconductor operation with randomization for wafer position according to claim 9, wherein higher weighting of the randomized wafer positions in the semiconductor operations indicates greater extent of influence on the wafer yield corresponding to the ID in the semiconductor operations.

11. The method of searching for key semiconductor operation with randomization for wafer position according to claim 9, wherein lower weighting of the randomized wafer positions in the semiconductor operations indicates smaller extent of influence on the wafer yield corresponding to the ID in the semiconductor operations.
